(19) United States
(12) Patent Application Publication
(10) Pub. No.: US 2013/0328575 A1
(43) Pub. Date: Dec. 12, 2013

(54) TOUCH SENSOR AND METHOD OF MANUFACTURING THE SAME

(71) Applicants: Seung Hyun Ra, Suwon (KR); Jin Uk Lee, Suwon (KR)

(72) Inventors: Seung Hyun Ra, Suwon (KR); Jin Uk Lee, Suwon (KR)

(73) Assignee: Samsung Electro-Mechanics Co., Ltd.,, Gyunggi-do (KR)

(21) Appl. No.: 13/586,801

(22) Filed: Aug. 15, 2012

(30) Foreign Application Priority Data
Jun. 7, 2012 (KR) 10-2012-0061056

(51) Int. Cl. G01R 27/00; H05K 13/00

(52) U.S. Cl. 324/649; 427/97.5

(57) ABSTRACT

Disclosed herein are a touch sensor and a method of manufacturing the same. The touch sensor includes: a transparent substrate; a resin layer formed on one surface of the transparent substrate; and an electrode formed on one surface of the resin layer, wherein one surface of the resin layer is formed with a substrate prominence and depression part having a prominence and depression shape.

### CROSS REFERENCE TO RELATED APPLICATION

This application claims the benefit of Korean Patent Application No. 10-2012-0061056, filed on Jun. 7, 2012, entitled “Touch Sensor and the Manufacturing Method”, which is hereby incorporated by reference in its entirety into this application.

### BACKGROUND OF THE INVENTION

1. Technical Field

The present invention relates to a touch sensor and a method of manufacturing the same.

2. Description of the Related Art

In accordance with the growth of computers using a digital technology, devices assisting computers have also been developed, and personal computers, portable transmitters and other personal information processors execute processing of text and graphics using a variety of input devices such as a keyboard and a mouse.

However, according to rapid advancement of an information-oriented society, since use of computers has increasingly expanded, it is difficult to efficiently operate a product using only the keyboard and the mouse currently serving as the input device. Therefore, the necessity for a device that is simple, has minimum malfunction, and is capable of easily inputting information has increased.

Furthermore, current techniques for input devices exceed the level of fulfilling general functions and thus are progressing towards techniques related to high reliability, durability, innovation, designing and manufacturing. To this end, a touch sensor has been developed as an input device capable of inputting information such as text and graphics.

This touch sensor is mounted on a display surface of an image display device such as an electronic organizer, a flat panel display device including a liquid crystal display (LCD) device, a plasma display panel (PDP), an electroluminescence (El) element, or the like, and a cathode ray tube (CRT) to thereby be used to allow a user to select desired information while viewing the image display device.

Meanwhile, the touch sensor is classified into a resistive type touch sensor, a capacitive type touch sensor, an electromagnetic type touch sensor, a surface acoustic wave (SAW) type touch sensor, and an infrared type touch sensor. These various types of touch sensors are adopted for an electronic product in consideration of not only signal amplification problems, resolution differences and the degree of difficulty of designing and manufacturing technology but also in light of optical properties, electrical properties, mechanical properties, resistance to the environment, input properties, durability and economic benefits. In particular, resistive and capacitive types are prevalently used at the present time.

Currently, as disclosed in Korean Patent Laid-Open Publication No. 2011-0102794, in the capacitive type touch sensor, an indium-tin oxide (ITO), a conductive polymer, a metal, or the like, has been used as a material of a transparent electrode.

However, in the case of forming the touch sensor by patterning the metal on a transparent substrate, a surface of the metal is smooth, such that reflection is easily generated. Therefore, when the display is viewed through the transparent substrate, the transparent electrode of the touch sensor is viewed with an eye, such that there is a problem in visibility.

### PRIOR ART DOCUMENT

### Patent Document

Patent Document 1. Korean Patent Laid-Open Publication No. 2011-0102794

### SUMMARY OF THE INVENTION

The present invention has been made in an effort to provide a touch sensor capable of decreasing reflection on a surface thereof, and a method of manufacturing the same.

According to a preferred embodiment of the present invention, there is provided a touch sensor including: a transparent substrate; a resin layer formed on one surface of the transparent substrate; and an electrode formed on one surface of the resin layer, wherein one surface of the resin layer is formed with a substrate prominence and depression part having a prominence and depression shape.

The resin layer may be made of an imprint resin.

The electrode may be a touch electrode.

One surface of the touch electrode positioned at the substrate prominence and depression part may be formed with an electrode prominence and depression part having a shape corresponding to that of the substrate prominence and depression part.

The touch electrode may be formed in a metal mesh pattern.

The touch electrode may be made of copper (Cu), aluminum (Al), gold (Au), silver (Ag), titanium (Ti), palladium (Pd), chromium (Cr), or a combination thereof.

The touch electrode may be made of metal silver formed by exposing/developing a silver salt emulsion layer.

The substrate prominence and depression part may be formed in a moth-eye shape.

The substrate prominence and depression part may have a pitch of 150 to 300 nm and a height one to three times larger than the pitch.

According to another preferred embodiment of the present invention, there is provided a method of manufacturing a touch sensor, the method including: a resin layer forming step of forming a resin layer on one surface of a transparent substrate; a substrate prominence and depression part forming step of forming a substrate prominence and depression part having a prominence and depression shape on one surface of the resin layer; and an electrode forming step of forming an electrode on the substrate prominence and depression part.

In the substrate prominence and depression part forming step, the resin layer may be made of an imprint resin, and one surface of the imprint resin may be imprinted to form the substrate prominence and depression part.

In the electrode forming step, one surface of the electrode positioned at the substrate prominence and depression part may be formed with an electrode prominence and depression part having a shape corresponding to that of the substrate prominence and depression part.

The electrode may be a touch electrode.

In the electrode forming step, the touch electrode may be formed by plating or sputtering.

The touch electrode may be formed in a metal mesh pattern.

The touch electrode may be made of copper (Cu), aluminum (Al), gold (Au), silver (Ag), titanium (Ti), palladium (Pd), chromium (Cr), or a combination thereof.

The touch electrode may be made of metal silver formed by exposing/developing a silver salt emulsion layer.

In the electrode forming step, the substrate prominence and depression part may be formed in a moth-eye shape.

In the substrate prominence and depression part forming step, a pitch of the substrate prominence and depression part may be 150 to 300 nm, and a height thereof may be one to three times larger than the pitch.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exploded perspective view showing a touch sensor according to a preferred embodiment of the present invention;

FIG. 2 is a side cross-sectional view showing the touch sensor according to the preferred embodiment of the present invention;

FIG. 3 is a flow chart showing a method of manufacturing a touch sensor according to a preferred embodiment of the present invention;

FIGS. 4 to 13 are cross-sectional views showing the method of manufacturing a touch sensor according to the preferred embodiment of the present invention in a process sequence;

FIG. 14 is a graph showing reflectivity of a prominence and depression part in the touch sensor manufactured by the method of manufacturing the touch sensor according to the preferred embodiment of the present invention; and

FIG. 15 is a graph showing transmittance of the touch sensor manufactured by the method of manufacturing the touch sensor according to the preferred embodiment of the present invention; and that of the touch sensor according to the prior art.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

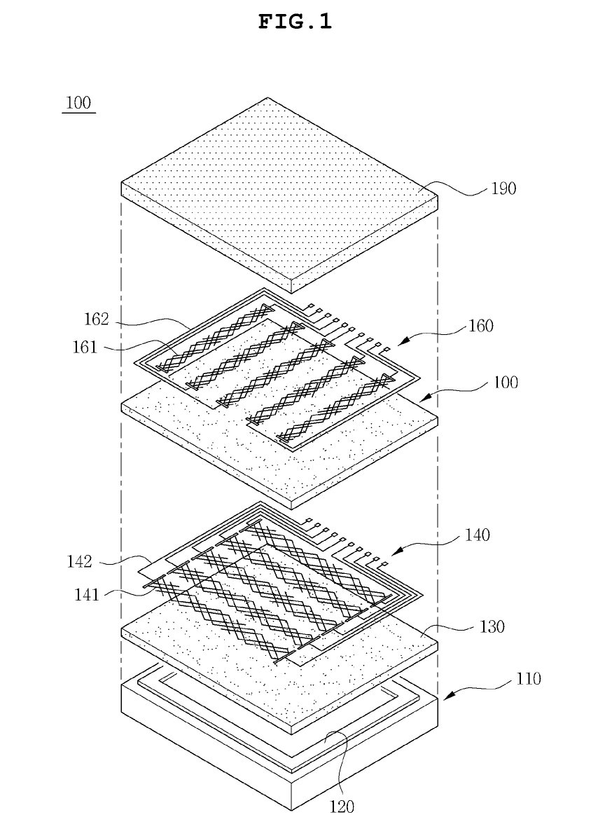

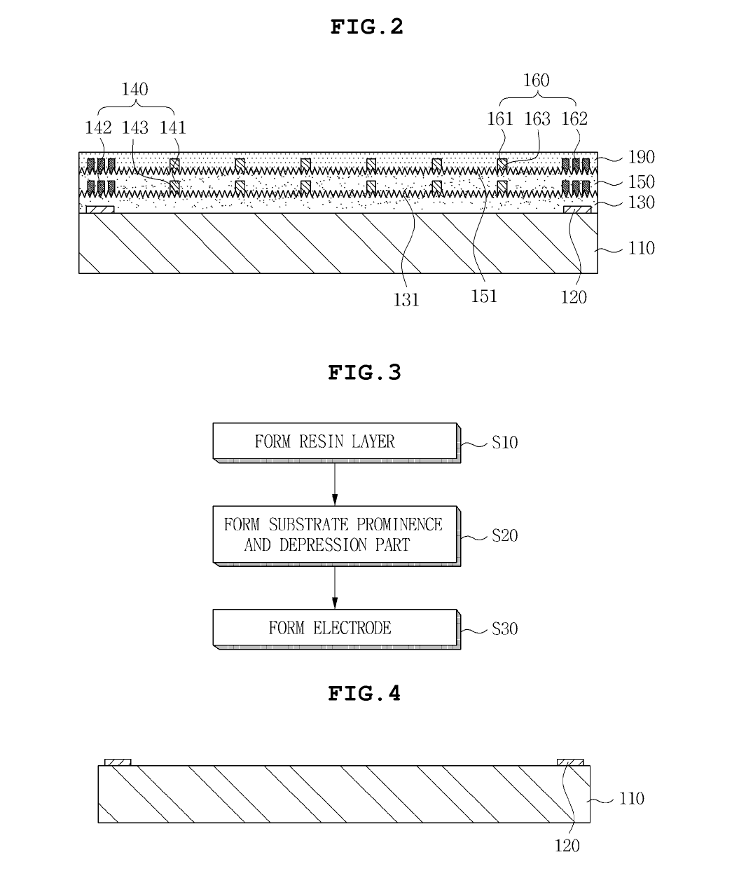

FIG. 1 is an exploded perspective view showing a touch sensor according to a preferred embodiment of the present invention, and FIG. 2 is a side cross-sectional view showing the touch sensor according to the preferred embodiment of the present invention.

Referring to FIGS. 1 and 2, the touch sensor 100 according to the preferred embodiment of the present invention include a transparent substrate 110, resin layers 130 and 150 formed on the transparent substrate 110, and an electrode formed on the resin layers 130 and 150. Here, the electrode is formed of touch electrodes 140 and 160.

Hereinafter, the touch sensor 100 according to the preferred embodiment of the present invention will be described in detail with reference to FIGS. 1 and 2.

Referring to FIGS. 1 and 2, the transparent substrate 110 is made of glass or film to provide a substrate part having an electrode formed thereon. Here, the transparent substrate 110 may be formed in a squared-plane shape having a predetermined thickness; however, a form of the transparent substrate 110 according to the preferred embodiment of the present invention is not limited thereto.

Referring to FIGS. 1 and 2, the resin layers 130 and 150 are formed on one surface of the transparent substrate 110.

In addition, the resin layers 130 and 150 may be made of an imprint resin. Here, the imprint resins may be made of a thermoplastic resin; however, the imprint resins 130 and 150 according to the preferred embodiment of the present invention are not limited thereto.

Referring to FIGS. 1 and 2, each of substrate prominence and depression parts 131 and 151 is formed in a prominence and depression shape on one surface of each of the resin layers 130 and 150.

Here, a pitch of each of the substrate prominence and depression parts 131 and 151 may be 150 to 300 nm, and a height thereof may be one to three times larger than the pitch.

In addition, the substrate prominence and depression parts 131 and 151 may have a moth-eye shape, but are not necessarily limited thereto.

In addition, the substrate prominence and depression parts 131 and 151 may be formed by laminating or applying the imprint resin on one surface of the transparent substrate 110 to form the resin layers 130 and 150, and then pressing one surface of the resin layers 130 and 150 using a stamp or the like.

Referring to FIGS. 1 and 2, touch electrodes 140 and 160 are formed on the substrate prominence and depression parts 131 and 151 which are one surface of the resin layers 130 and 150. Here, although the case in which one surface of each of the resin layers 130 and 150 is an upper surface of each of the resin layers 130 and 150 is shown in FIG. 1, one surface of each of the resin layers 130 and 150 of the present invention is not limited to the upper surface of the resin layers 130 and 150, but may be a lower surface of each of the resin layers 130 and 150.

In addition, the touch electrode 140 and 160 may be formed by depositing a metal on one surface of the substrate prominence and depression parts 131 and 151 using sputtering, plating, or the like.

In addition, the touch electrodes 140 and 160 includes electrode patterns 141 and 161 and electrode wirings 142 and 162 that sense a touch.

Further, the electrode patterns 141 and 161 may include a first electrode pattern 141 and a second electrode pattern 161, and the electrode wirings 142 and 162 may include a first electrode wiring 142 and a second electrode wiring 162.

Here, the first electrode wiring 142 receiving an electrical signal from the first electrode pattern 141 is formed at an edge of the first electrode pattern 140, and the second electrode wiring 162 receiving an electrical signal from the second electrode pattern 161 is formed at an edge of the second electrode pattern 161.

In addition, the electrode patterns 141 and 161 may be made of a metal mesh. Here, the metal mesh may be formed in a mesh pattern using copper (Cu), aluminum (Al), gold (Au), silver (Ag), titanium (Ti), palladium (Pd), chromium (Cr), or a combination thereof.

Meanwhile, in the case in which the electrode patterns 141 and 161 are made of copper (Cu), the substrate prominence and depression parts 131 and 151 prevent light from being reflected. Therefore, a separate black oxide treatment for preventing the light from being reflected on the surface of the electrode patterns 141 and 161 may be omitted.

In addition, in the electrode patterns 141 and 161, a line width is formed to be 7 μm or less, and a pitch is formed to be 900 μm or less, thereby making it possible to improve the visibility. However, the line width and the pitch of the electrode patterns 141 and 161 according to the preferred embodiment of the present invention are not limited thereto.

Further, the electrode patterns 141 and 161 may also be made of metal silver formed by exposing and developing a silver salt emulsion layer, in addition to the above-mentioned metal.

Meanwhile, referring to FIGS. 1 and 2, the touch sensor 100 according to the preferred embodiment of the present invention further include a protective layer 190 laminated and formed on one surface of the resin layer 151 having the touch electrode 160 thereon. Here, the protective layer 190 protects the touch electrode 160 formed on the resin layer 150 from moisture, impact, or an external environment.

Meanwhile, referring to FIGS. 1 and 2, in the case in which the electrode wirings 142 and 162 are made of a metal such as a silver paste, the electrode wirings 142 and 162 may be recognized from the outside. Therefore, in order to prevent this problem, a cover film 120 may be formed along the edge of one surface of the transparent substrate 110. The cover film 120 may be formed by printing an ink having low brightness such as a black ink on one surface of the transparent substrate 110.

In the touch sensor 100 according to the preferred embodiment of the present invention as described above, the substrate prominence and depression parts 131 and 151 are formed on one surface of the transparent substrate 110, thereby making it possible to decrease or prevent reflection of the light, such that the visibility may be improved.

In addition, in the case in which the touch electrodes 140 and 161 are formed in the metal mesh pattern, the visibility is improved due to the substrate prominence and depression parts 131 and 151 formed on one surface of the transparent substrate 110 or electrode prominence and depression parts (143 and 163) formed on a lower surface of the touch electrode 140 and 161, thereby making it possible to omit the separate black oxide treatment for improving the visibility.

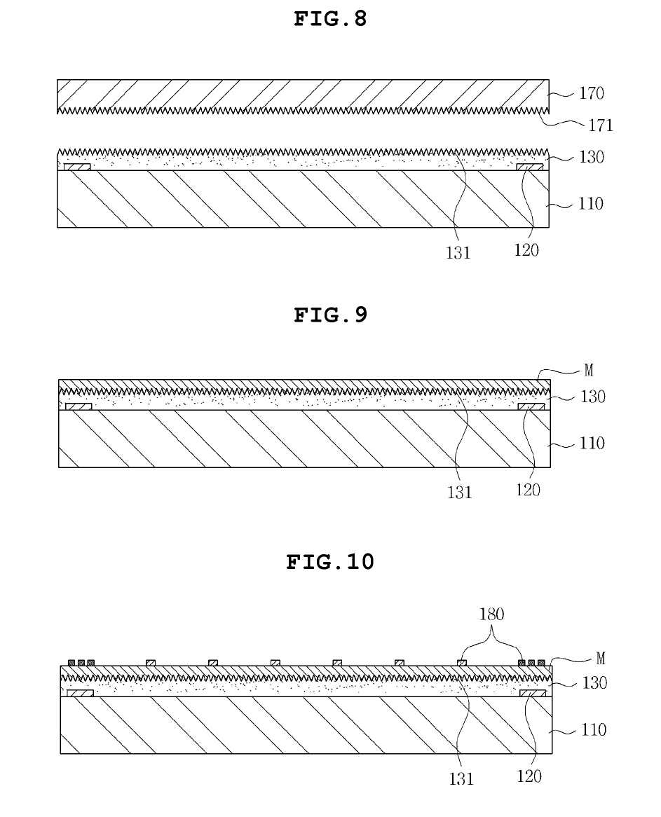

FIG. 3 is a flow chart showing a method of manufacturing a touch sensor according to a preferred embodiment of the present invention; and FIGS. 4 to 13 are cross-sectional views showing the method of manufacturing the touch sensor according to the preferred embodiment of the present invention in a process sequence.

Referring to FIG. 3, the method of manufacturing the touch sensor according to the preferred embodiment of the present invention include a resin layer 130 forming step (S10), a substrate prominence and depression part forming step (S20), and an electrode forming step (S30).

Hereinafter, the method of manufacturing the touch sensor according to the preferred embodiment of the present invention will be described in more detail with reference to FIGS. 3 to 13. In addition, the method of manufacturing the touch sensor according to the preferred embodiment of the present invention is the method of manufacturing the touch sensor 100 according to the preferred embodiment of the present invention. Therefore, the overlapped description will be omitted, and like reference numerals refers to like components.

Referring to FIGS. 3 and 4, in the resin layer 130 forming step (S10), the resin layer 130 is formed on one surface of the transparent substrate 110. Here, the resin layer 130 may be made of an imprint resin. Here, the imprint resin may be made of a thermoplastic resin, which is not limited thereto.

Referring to FIGS. 3 and 5 to 7, in the substrate prominence and depression part forming step (S20), one surface of the resin layer 130 is imprinted to form a prominence and depression surface.

Specifically, when one surface of the resin layer 130 is pressurized using a stamp 170 having a protrusion part 171 protruded on a lower surface thereof, a prominence and depression groove is formed at a portion pressurized by the protrusion part 171 in one surface of the resin layer 130, thereby making it possible to form the substrate prominence and depression part 131 at the resin layer 130. Here, although the substrate prominence and depression part 131 may have a moth-eye shape in which a plurality of protrusions having, for example, a conical shape, a pyramidal shape, or the like, are protruded in parallel with each other, the substrate prominence and depression part 131 according to the preferred embodiment of the present invention is not limited to having the above-mentioned shape.

Here, the substrate prominence and depression part 131 may be formed so that a pitch thereof is 150 to 300 nm, and a height thereof is one to three times larger than the pitch.

Referring to FIGS. 3 and 9 to 11, in the electrode laminating step (S30), the touch electrode 140 is laminated on the substrate prominence and depression part 131 of the resin layer 130. Here, the electrode laminating step (S30) includes a metal layer laminating step, a resist forming step, an exposing step, and a resist removing step.

Referring to FIG. 9, in the metal layer laminating step, the metal layer is formed on the substrate prominence and depression part 131 of the resin layer 130. Here, an electrode prominence and depression part (143) may be formed on a lower surface of the metal layer so as to correspond to the substrate prominence and depression part 131.

In addition, the forming of the metal layer may be formed by plating the metal or sputtering; however, the forming of the metal layer of the present invention is not necessarily limited thereto.

Referring to FIG. 10, in the resist laminating step, the resist 180 is selectively formed on one surface of the metal layer. Here, the resist 180 may be made of an insulating material.

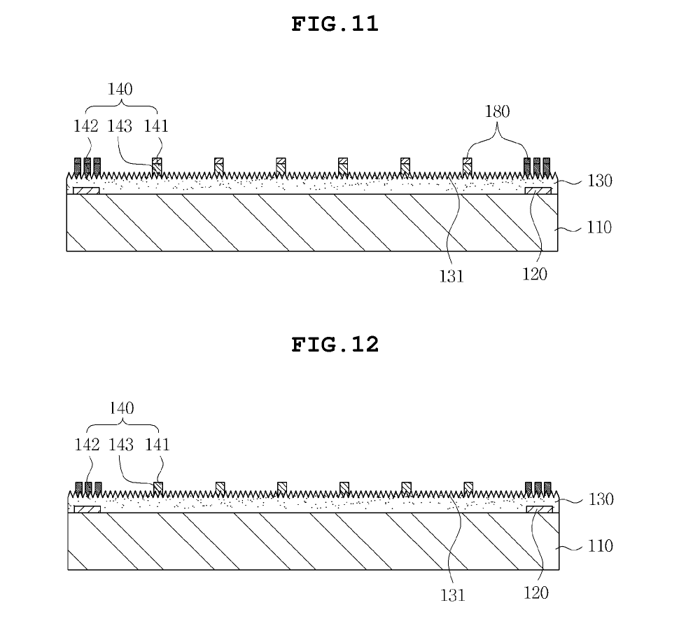

Referring to FIG. 11, in the exposing step, one surface of the metal layer on which the resist 180 is selectively formed is exposed to remove a portion in which the resist is not formed on one surface of the metal layer. Therefore, the metal layer having the resist 180 formed thereon and positioned in the lower part of the resist 180 forms a pattern, such that the touch electrode 160 may be formed. Here, the touch electrode 160 may be formed in a mesh pattern.

Referring to FIG. 12, in the resist removing step, the resist 180 formed on the metal layer is removed. Here, the resist 180 may be removed by a removing liquid; however, the removing of the resist 180 is not limited thereto.

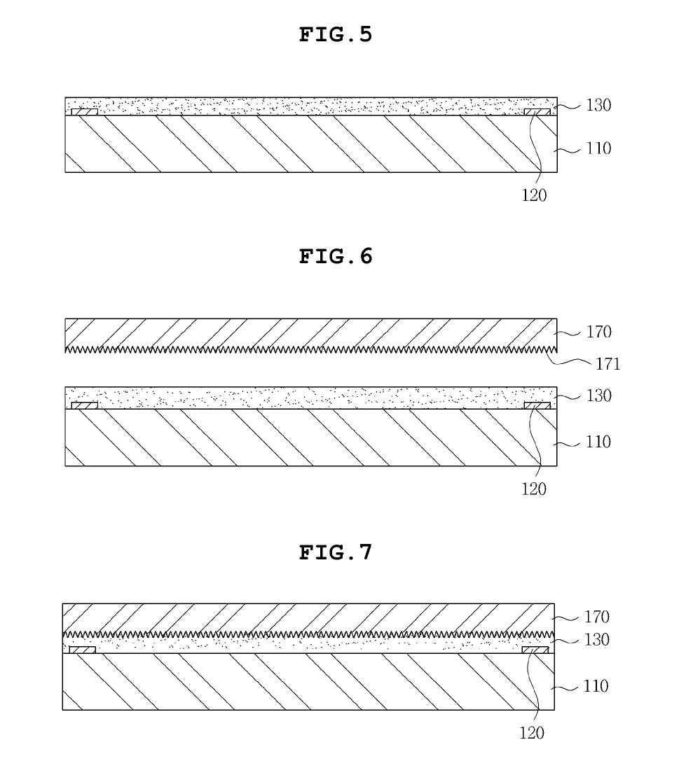

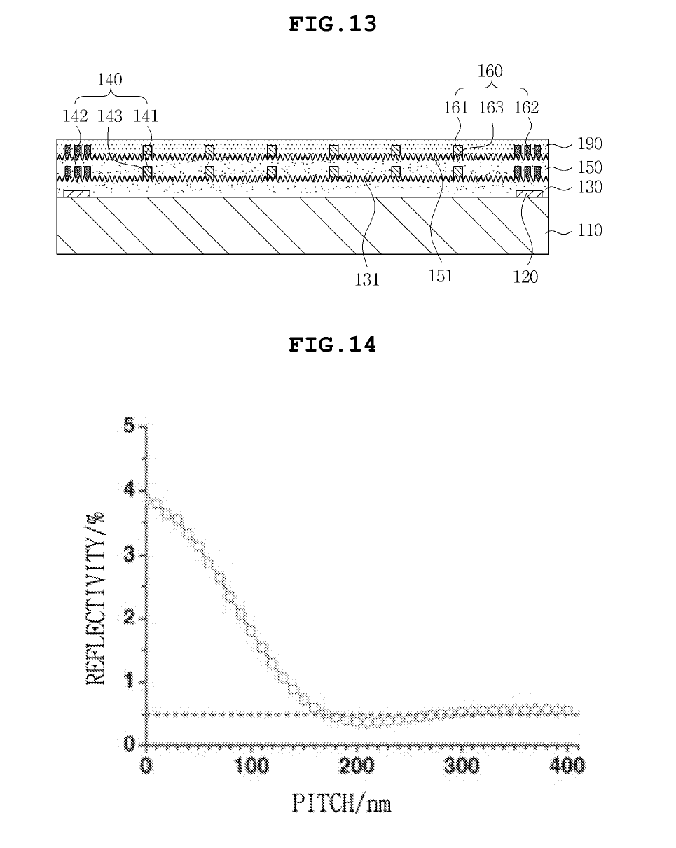

Meanwhile, referring to FIG. 13, in the method of manufacturing the touch sensor according to the preferred embodiment of the present invention, the touch electrodes 140 and 160 may have a plurality of layers. Here, the touch electrodes 140 and 160 may be configured of a first touch electrode 140 and a second touch electrode 160. Here, the process of manufacturing a touch sensor described with reference to FIGS. 5 to 11 is performed once again, thereby making it possible to form a second touch electrode 160 over the first touch electrode 140 shown in FIG. 13.

In addition, in order to form the second touch electrode 160, the imprint resin is additionally applied or laminated on one surface of the resin layer 130 having the first touch electrode 140 formed thereon, such that the resin layer 150 is formed, and the substrate prominence and depression part 151 is formed on one surface of the resin layer 150 additionally formed by the stamp 170.

Here, the metal layer is formed on one surface of the substrate prominence and depression part 151, the resist is selectively laminated, and exposure is performed on the metal layer to remove a portion in which the resist is not laminated, thereby making it possible to form the second touch electrode 160. Here, the resist laminated on the metal layer is removed. Here, since the forming of the second touch electrode 160 is the same as the forming of the first touch electrode 140, the detailed description thereof will be omitted.

Meanwhile, the first touch electrode 140 and the second touch electrode 160 may be formed so as to intersect with each other. Here, for example, the first touch electrode 140 may be formed in a horizontal direction, and the second touch electrode 160 may be formed in a vertical direction, which is not limited thereto.

In addition, the first touch electrode 140 and the second touch electrode 160 may be made of copper (Cu), aluminum (Al), gold (Au), silver (Ag), titanium (Ti), palladium (Pd), chromium (Cr), or a combination thereof; however, the material of the touch electrodes 140 and 160 of the present invention is not limited thereto.

In addition, the first touch electrode 140 and the second touch electrode 160 may be made of metal silver formed by exposing/developing the silver salt emulsion layer.

FIG. 14 is a graph showing reflectivity of the prominence and depression part in the touch sensor manufactured by the method of manufacturing the touch sensor according to the preferred embodiment of the present invention.

It may be appreciated from FIG. 14 that in the case in which the pitch of the prominence and depression part formed in the prominence and depression shape in the touch sensor manufactured by the method of manufacturing the touch sensor according to the preferred embodiment of the present invention is 150 to 300 nm, the reflectivity is 0.5 or less. Here, a width of the prominence and depression of the prominence and depression part measured at the time of measuring the reflectivity of the prominence and depression part is 85 nm, which is not limited thereto.

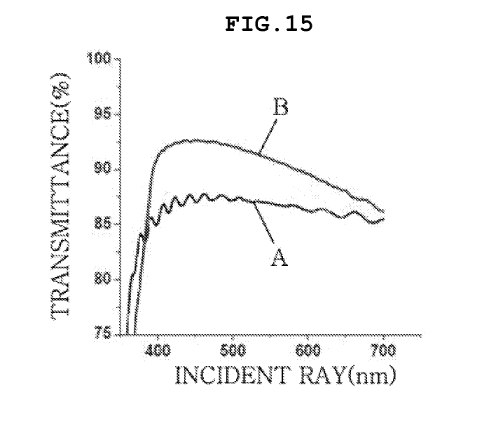

FIG. 15 is a graph showing transmittance of the touch sensor manufactured by the method of manufacturing the touch sensor according to the preferred embodiment of the present invention; and that of the touch sensor according to the prior art.

As shown in FIG. 15, when an incident ray of beam (light) transmits the touch sensor, it may be appreciated that the transmittance of the touch sensor (B) of the present invention in which the prominence and depression part is formed is higher than that of the touch sensor (A) of the prior art in which the prominence and depression part is not formed.

Therefore, the method of manufacturing the touch sensor according to the preferred embodiment of the present invention forms the substrate prominence and depression parts 131 and 151 on one surface of the transparent substrate 110, thereby making it possible to decrease the reflection of the light, such that the visibility may be improved.

In addition, at the time of forming the touch electrodes 140 and 160 formed in the metal mesh pattern, the visibility is improved due to the substrate prominence and depression parts 131 and 151 formed on one surface of the transparent substrate 110 or the electrode prominence and depression parts (143 and 163) formed on a lower surface of the touch electrode 140 and 160, thereby making it possible to omit the separate black oxide treatment which improves the visibility.

As set forth above, according to the preferred embodiment of the present invention, the reflection generated on the surface of the touch sensor is decreased, thereby making it possible to improve the visibility of the touch sensor.

In addition, according to the preferred embodiment of the present invention, at the time of forming the touch electrode in the metal mesh pattern, the black oxide treatment may be omitted.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims

What is claimed is:

1. A touch sensor comprising:
a transparent substrate;
a resin layer formed on one surface of the transparent substrate; and
an electrode formed on one surface of the resin layer,
wherein one surface of the resin layer is formed with a substrate prominence and depression part having a prominence and depression shape.

2. The touch sensor as set forth in claim 1, wherein the resin layer is made of an imprint resin.

3. The touch sensor as set forth in claim 1, wherein the electrode is a touch electrode sensing a touch.

4. The touch sensor as set forth in claim 3, wherein one surface of the touch electrode positioned at the substrate prominence and depression part is formed with an electrode prominence and depression part having a shape corresponding to that of the substrate prominence and depression part.

5. The touch sensor as set forth in claim 3, wherein the touch electrode is formed in a metal mesh pattern.

6. The touch sensor as set forth in claim 5, wherein the touch electrode is made of copper (Cu), aluminum (Al), gold (Au), silver (Ag), titanium (Ti), palladium (Pd), chromium (Cr), or a combination thereof.

7. The touch sensor as set forth in claim 5, wherein the touch electrode is made of metal silver formed by exposing/developing a silver salt emulsion layer.

8. The touch sensor as set forth in claim 1, wherein the substrate prominence and depression part is formed in a moth-eye shape.

9. The touch sensor as set forth in claim 1, wherein the substrate prominence and depression part has a pitch of 150 to 300 nm and a height one to three times larger than the pitch.

10. A method of manufacturing a touch sensor, the method comprising:
a resin layer forming step of forming a resin layer on one surface of a transparent substrate;
a substrate prominence and depression part forming step of forming a substrate prominence and depression part having a prominence and depression shape on one surface of the resin layer; and
an electrode forming step of forming an electrode on the substrate prominence and depression part.

11. The method as set forth in claim 10, wherein in the substrate prominence and depression part forming step,
the resin layer is made of an imprint resin, and
one surface of the imprint resin is imprinted to form the substrate prominence and depression part.

12. The method as set forth in claim 10, wherein in the electrode forming step, one surface of the electrode positioned at the substrate prominence and depression part is formed with an electrode prominence and depression part having a shape corresponding to that of the substrate prominence and depression part

13. The method as set forth in claim 10, wherein the electrode is a touch electrode sensing a touch.

14. The method as set forth in claim 13, wherein in the electrode forming step, the touch electrode is formed by plating or sputtering.

15. The method as set forth in claim 13, wherein the touch electrode is formed in a metal mesh pattern.

16. The method as set forth in claim 15, wherein the touch electrode is made of copper (Cu), aluminum (Al), gold (Au), silver (Ag), titanium (Ti), palladium (Pd), chromium (Cr), or a combination thereof.

17. The method as set forth in claim 15, wherein the touch electrode is made of metal silver formed by exposing/developing a silver salt emulsion layer.

18. The method as set forth in claim 10, wherein in the electrode forming step, the substrate prominence and depression part is formed in a moth-eye shape.

19. The method as set forth in claim 11, wherein in the substrate prominence and depression part forming step, a pitch of the substrate prominence and depression part is 150 to 300 nm, and a height thereof is one to three times larger than the pitch.
